(19) United States
(12) Patent Application Publication
(10) Pub. No.: US 2025/0296247 A1
(43) Pub. Date: Sep. 25, 2025

(54) CASSETTE GRIPPING APPARATUS

(71) Applicant: HANWHA SOLUTIONSCORPORATION, Seoul (KR)

(72) Inventors: Jong Won LEE, Seoul (KR); Seung Jin Kim, Seoul (KR); Hyun Seok Jung, Seoul (KR); Yong Ho Choi, Seoul (KR)

(73) Assignee: HANWHA SOLUTIONS CORPORATION, Seoul (KR)

(21) Appl. No.: 19/086,356

(22) Filed: Mar. 21, 2025

(30) Foreign Application Priority Data
Mar. 22, 2024 (KR) 10-2024-0039789

(51) Int. Cl. B25J 15/02; B25J 15/00; B25J 19/00

(52) U.S. Cl. CPC B25J 15/0253; B25J 15/0028; B25J 19/0091

(57) ABSTRACT

The present invention provides a cassette gripping apparatus including a first plate, a first cylinder provided on one side of the first plate, and grippers coupled to the first cylinder to grip both sides of a cassette, and the grippers operate to move away from or toward each other with respect to opposite vertices in a diagonal direction of the cassette.

The present invention provides a cassette gripping apparatus including a housing, a third cylinder provided on one side of the housing, a fourth cylinder provided on the opposite side of the third cylinder on the housing, a first gripper coupled to the third cylinder to grip one side of a cassette, and a second gripper coupled to the fourth cylinder to grip the other side of the cassette, and the first gripper and the second gripper operate to move away from or toward each other with respect to opposite vertices in a diagonal direction of the cassette.

Further, the present invention provides a cassette gripping apparatus including a first transport module configured to grip one end of a cassette and move the cassette in a first direction defined as a direction from a first location to a second location, and a second transport module configured to grip the other end of the cassette and move the cassette in the first direction, the first transport module includes a first cassette gripping apparatus configured to grip an upper end of the cassette, the second transport module includes a second cassette gripping apparatus configured to grip a lower end of the cassette, and the second transport module includes a first gripper and a second gripper reciprocating in different directions on the second cassette gripping apparatus.

### CROSS-REFERENCE TO RELATED APPLICATION

The present application claims priority and the benefit of Korean Patent Application No. 10-2024-0039789, filed on Mar. 22, 2024 in the Korean Intellectual Property Office, the entire disclosure of which is incorporated herein by reference.

### BACKGROUND

### 1. Field of the Invention

The present invention relates to a cassette gripping apparatus, and more specifically, to a cassette gripping apparatus capable of gripping and safely moving a cassette in which a plurality of substrates are mounted.

### 2. Discussion of Related Art

Generally, a cassette supply apparatus is installed to continuously supply a plurality of substrates to the next process.

In such a conventional cassette supply apparatus, a substrate transport module continuously grips and extracts substrates one by one from a cassette and transports the substrates to the next process, and in this case, a time for the substrate transport module to transport the substrates and a time to perform cassette replacement after all the substrates are extracted from the cassette act as factors that increase a cycle time of an entire system.

Further, there is a problem in that impact is transmitted to the substrates during a process of gripping a cassette through a cassette gripping apparatus or the cassette is required to be aligned before the cassette is gripped, and there is another problem in that impact is transmitted to the cassette or the cassette gripping apparatus while the cassette is transferred from a cassette gripping apparatus to another cassette gripping apparatus.

### SUMMARY OF THE INVENTION

The present invention has been made to solve such problems and is directed to providing a cassette gripping apparatus capable of gripping and safely moving a cassette in which a plurality of substrates are mounted.

Objects of the present invention are not limited to the above-mentioned object, and other objects that have not been mentioned can be clearly understood by those skilled in the art from the description below.

According to an aspect of the present invention, there is provided a cassette gripping apparatus including a first plate, a first cylinder provided on one side of the first plate, and grippers coupled to the first cylinder to grip both sides of a cassette, wherein the grippers operate to move away from or toward each other with respect to opposite vertices in a diagonal direction of the cassette.

The gripper may include a first guide member and a second guide member disposed on two sides adjacent to each other at one of the vertices of the quadrilateral cassette, a first connection member configured to connect the first guide member and the second guide member to one side of the first cylinder, a third guide member and a fourth guide member disposed on two sides adjacent to each other at the other vertex of the cassette, and a second connection member configured to connect the third guide member and the fourth guide member to the other side of the first cylinder.

When the first and second guide members and the third and fourth guide members move toward each other, the cassette may be automatically aligned in x-axis and y-axis directions.

Each of the first to fourth guide members may include a flange member that protrudes in a circumferential direction at a tip thereof and supports the other side of the cassette.

The cassette gripping apparatus may further include a second cylinder that is adjacent to the first cylinder and is configured to press and fix one side of the cassette, wherein, when the second cylinder presses the one side of the cassette, the other side of the cassette may be supported by and fixed to the flange member.

The cassette gripping apparatus may further include an impact absorption part provided on the other side of the first plate, wherein the impact absorption part may include a second plate spaced apart from the other side of the first plate, a plurality of dampers elastically connecting the first plate and the second plate, and a spacing maintenance part configured to selectively maintain a set spacing between the first plate and the second plate.

According to another aspect of the present invention, there is provided a cassette gripping apparatus including a housing, a third cylinder provided on one side of the housing, a fourth cylinder provided on the opposite side of the third cylinder on the housing, a first gripper coupled to the third cylinder to grip one side of a cassette, and a second gripper coupled to the fourth cylinder to grip the other side of the cassette, wherein the first gripper and the second gripper operate to move away from or toward each other with respect to opposite vertices in a diagonal direction of the cassette.

The first gripper may be disposed to reciprocate in a diagonal direction from one of the vertices to the other vertex in the diagonal direction of the quadrilateral cassette, and the second gripper may be disposed to reciprocate in a direction perpendicular to one side adjacent to the other vertex.

The second gripper may be formed to have a relatively shorter movement distance than the first gripper.

The first gripper may include a first guide member and a second guide member disposed on respective adjacent sides at one vertex of the cassette, and a first connection member connected to the third cylinder to move the first guide member and the second guide member away from or toward the one vertex, and the second gripper includes a third guide member and a fourth guide member disposed on respective adjacent sides at the other vertex of the cassette, and a second connection member connected to the fourth cylinder to move the third guide member and the fourth guide member away from or toward a side adjacent to the other vertex.

When the first gripper and the second gripper move toward each other, the cassette may be automatically aligned in x-axis and y-axis directions.

The cassette gripping apparatus may further include a pressing module that includes a fifth cylinder disposed between the third cylinder and the fourth cylinder on the housing, and a pressing plate connected to the fifth cylinder and disposed to linearly reciprocate toward the cassette from the housing.

The cassette gripping apparatus may further include a plurality of roller parts disposed between the pressing module and the cassette on the housing and configured to move the cassette in a rolling manner when the roller parts are positioned higher than the pressing module.

The pressing plate may include a horizonal plate connected to the fifth cylinder on the housing and provided to move up and down and a plurality of vertical plates protruding toward the cassette on the horizontal plate and disposed between the roller part and the other adjacent roller part to be spaced apart from the respective roller parts.

According to still another aspect of the present invention, there is provided a cassette gripping apparatus including a first transport module configured to grip one end of a cassette and move the cassette in a first direction defined as a direction from a first location to a second location and a second transport module configured to grip the other end of the cassette and move the cassette in the first direction, wherein the first transport module includes a first cassette gripping apparatus configured to grip an upper end of the cassette, the second transport module includes a second cassette gripping apparatus configured to grip a lower end of the cassette, and the second transport module includes a first gripper and a second gripper reciprocating in different directions on the second cassette gripping apparatus.

Specific details of other embodiments are included in the detailed description and drawings.

### BRIEF DESCRIPTION OF THE DRAWINGS

A detailed description of preferred embodiments of the present invention to be described below as well as the summary described above will be better understood when read in conjunction with the accompanying drawings. For the purpose of illustration of the present invention, preferred embodiments are shown in the drawings. However, it should be understood that the present invention is not limited to the precise disposition and means that are illustrated.

FIG. 1 is a perspective view schematically illustrating a continuous cassette supply apparatus according to an embodiment of the present invention;

FIG. 2 is a front view illustrating the continuous cassette supply apparatus illustrated in FIG. 1 from the front;

FIG. 3 is a perspective view illustrating a first transport module of the continuous cassette supply apparatus illustrated in FIG. 2;

FIG. 4 is a perspective view illustrating a first cassette gripping apparatus of the first transport module illustrated in FIG. 3;

FIGS. 5A and 5B are front views illustrating the first cassette gripping apparatus illustrated in FIG. 4;

FIG. 6 is a reference view illustrating the first cassette gripping apparatus illustrated in FIGS. 5A and 5B from above;

FIG. 7 is a perspective view illustrating a second transport module of the continuous cassette supply apparatus illustrated in FIG. 2;

FIG. 8 is a reference view illustrating a second cassette gripping apparatus of the first transport module illustrated in FIG. 7;

FIG. 9 is a reference diagram illustrating an operating state of the second cassette gripping apparatus illustrated in FIG. 8; and

FIG. 10 is a reference diagram illustrating the second cassette gripping apparatus illustrated in FIG. 9 from above.

### DETAILED DESCRIPTION OF EXEMPLARY EMBODIMENTS

Hereinafter, preferred embodiments of the present invention will be described in detail with reference to the accompanying drawings. The advantages and features of the present invention and methods for achieving the advantages and features will become clear by referencing the embodiments that will be described in detail later together with the accompanying drawings. However, the present invention is not limited to the embodiments that will be disclosed below, but may be implemented in various different forms, the embodiments are provided only to make the disclosure of the present invention complete and to fully inform those skilled in the art to which the present invention belongs of the scope of the invention, and the present invention is defined only by the claims. The same reference signs refer to the same components throughout the specification.

The present invention can be subject to various modifications and have several embodiments, and specific embodiments will be illustrated in the drawings and described.

However, this is not intended to limit the present invention to specific embodiments, and it should be understood to include all modifications, equivalents, and substitutions included in the spirit and technical scope of the present invention.

Terms including ordinal numbers such as “first” and “second” may be used to describe various components, but the components are not limited by the terms.

The terms are used only for the purpose of distinguishing one component from another component.

For example, a second component may be referred to as a first component, and similarly, a first component may also be referred to as a second component without departing from the scope of the present invention.

The term “and/or” includes a combination of a plurality of related items as described or any of the plurality of related items as described.

When a component is said to be “connected” or “coupled” to another component, it should be understood that the component may be directly connected or coupled to the other component, or there may be other components disposed in between.

On the other hand, when a component is said to be “directly connected” or “directly coupled” to another component, it should be understood that there are no other components disposed in between.

The terms used in the present application are used only to describe specific embodiments and are not intended to limit the present invention.

A singular expression includes a plural expression unless the context clearly indicates otherwise.

It should be understood that in the present application, terms such as “include” and “have” are intended to designate the presence of a feature, number, step, operation, component, part, or combination thereof described in the specification, but do not preclude the possibility of the presence or addition of one or more other features, numbers, steps, operations, components, parts, or combinations thereof.

Hereinafter, embodiments will be described in detail with reference to the accompanying drawings, the same or corresponding components will be denoted by the same reference signs throughout the drawings, and redundant descriptions thereof will be omitted.

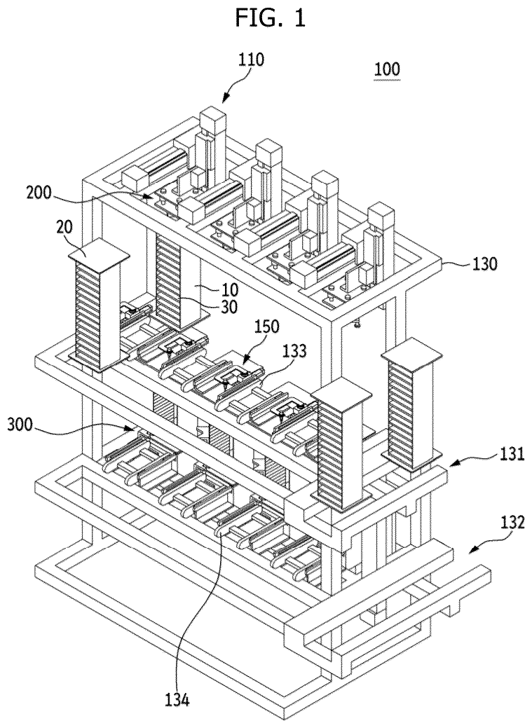

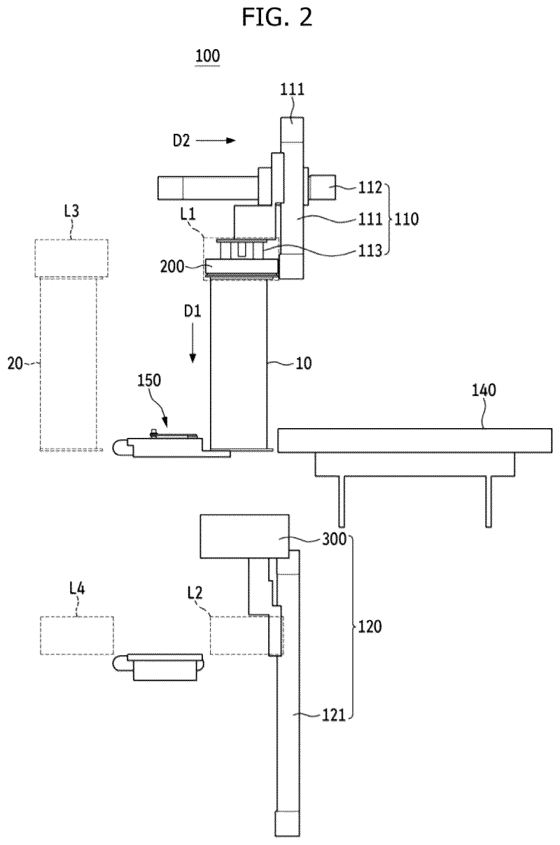

FIG. 1 is a perspective view schematically illustrating a continuous cassette supply apparatus of the present invention, and FIG. 2 is a front view illustrating the continuous cassette supply apparatus illustrated in FIG. 1 from the front.

Referring to FIGS. 1 and 2, a continuous cassette supply apparatus 100 may include first transport modules 110, second transport modules 120, and a frame module 130.

First, the first transport module 110 may grip one end of a first cassette 10 that is supplied relatively earlier, move from a first location L1 to a second location L2 in a vertical direction, and move from a third location L3 to the first location L1 in a horizontal direction. Here, an example in which the one end of the first cassette 10 is an upper end of the first cassette 10 will be described.

The first transport module 110 may include a first vertical movement part 111, a first horizontal movement part 112, and a first cassette gripping apparatus 200 according to one embodiment of the present invention.

Here, the first location L1 may be disposed in an upper portion in a vertical direction from an installation surface, and the second location L2 may be disposed in a lower portion. In this case, a direction from the first location L1 to the second location L2 is referred to as a first direction D1. Further, the third location L3 may be disposed in a horizontal direction from the first location L1, and a direction from the third location L3 to the first location L1 is referred to as a second direction D2. Further, an example in which the first direction D1 and the second direction D2 are orthogonal to each other will be described, but the present invention is not limited thereto.

The first vertical movement part 111 may move the cassette from the first location L1 to the second location L2 in the first direction D1. In this case, the cassette may be installed so that the cassette can be moved from the first vertical movement part 111 by the first gripper 113 to be described later. It is apparent that the first transport module 110 transfers the first cassette 10 to the second transport module 120 midway instead of moving to the second location L2, and the first cassette 10 moves to the second location L2 through the second transport module 120.

Further, the first horizontal movement part 112 may move the first vertical movement part 111 between the first location L1 and the third location L3. At the third location L3, new cassettes supplied on the frame module 130 to be described later may be positioned.

Further, the first cassette gripping apparatus 200 may be fixed to the first vertical movement part 111 while gripping the upper end of the first cassette 10.

Therefore, the newly supplied first cassette 10 is fixed at the third location L3 by the first cassette gripping apparatus 200, moved to the first location L1 by the first horizontal movement part 112, and then moved in the first direction D1 by the first vertical movement part 111.

Further, the second transport module 120 may grip the other end of the first cassette 10, move toward the second location L2 in the vertical direction, and move from the second location L2 to a fourth location L4 in the horizontal direction. Here, the other end of the first cassette 10 may be a lower end of the first cassette 10.

The second transport module 120 may include a second vertical movement part 121 and a second cassette gripping apparatus 300 according to another embodiment of the present invention.

The second vertical movement part 121 may receive the first cassette 10 transferred from the first vertical movement part 111 and move toward the second location L2 while gripping the first cassette 10 using the second cassette gripping apparatus 300.

Here, the first vertical movement part 111 and the second vertical movement part 121 may move stepwise in units of pitch P corresponding to a spacing between one substrate and another adjacent substrate when vertically moving down in the first direction D1. When the first vertical movement part 111 and the second vertical movement part 121 move down stepwise in units of pitch P in this way, the substrates may be extracted one by one by a separation module 140. Here, the separation module 140 may extract one substrate 30 from the inside of the cassette and then transfer the substrate 30 to the next process.

Further, the first vertical movement part 111 and the second vertical movement part 121 or the first cassette gripping apparatus 200 and the second cassette gripping apparatus 300 may be disposed to overlap each other with respect to the first direction D1.

After the first cassette 10 is transferred from the first transport module 110 to the second transport module 120, the first cassette gripping apparatus 200 in the first transport module 110 may move to the third location L3 again, grip the second cassette 20 on which a plurality of new substrates are mounted, and move to the first location L1. In this case, it is preferable for the first transport module 110 to move the second cassette 20 to the first location L1 before all the substrates 30 inside the first cassette 10 transferred to the second transport module 120 are extracted. It is apparent that the second cassette 20 may move down in units of pitch P from the first location L1 in the first direction D1 in response to the first cassette 10 moving down in units of pitch P, so that the lowest substrate 30 is positioned at a horizontal location with respect to the separation module 140, thereby allowing the first cassette 10 to be separated and discharged and the substrates of the second cassette 20 to be continuously supplied immediately.

The frame module 130 may have the first transport modules 110 and the second transport modules 120 mounted thereon and support the first transport module 110 and the second transport module 120 so that the first transport module 110 and the second transport module 120 can move relative to each other. In the present embodiment, as illustrated in FIG. 1, for example, four first transport modules 110 and four second transport modules 120 are installed on the frame module 130, and the number of the transport modules is not limited thereto.

Further, the frame module 130 may include an insertion part 131 and a collection part 132.

The insertion part 131 may be disposed on a relatively higher side and may supply a plurality of cassettes to the third location L3.

Further, the collection part 132 may be disposed on a relative lower side with respect to the insertion part 131, may move the cassette separated from the second cassette gripping apparatus 300 at the second location L2 to the fourth location L4 present in a horizontal direction, and discharge the cassette to the outside.

Further, the frame module 130 may be provided with an upper conveyor structure 133 for moving the cassette from the third location L3 to the first location L1 and a lower conveyor structure 134 for moving the cassette from the second location L2 to the fourth location L4.

In the continuous cassette supply apparatus described above, the cassette gripping apparatus according to the embodiment of the present invention may include the first cassette gripping apparatus 200 of the first transport module 110 and the second cassette gripping apparatus 300 of the second transport module 120.

Hereinafter, the first cassette gripping apparatus 200 and the second cassette gripping apparatus 300 will be described in detail.

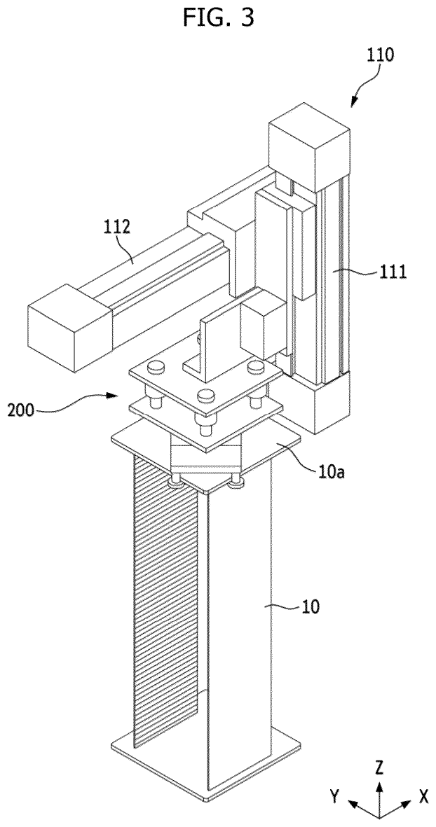

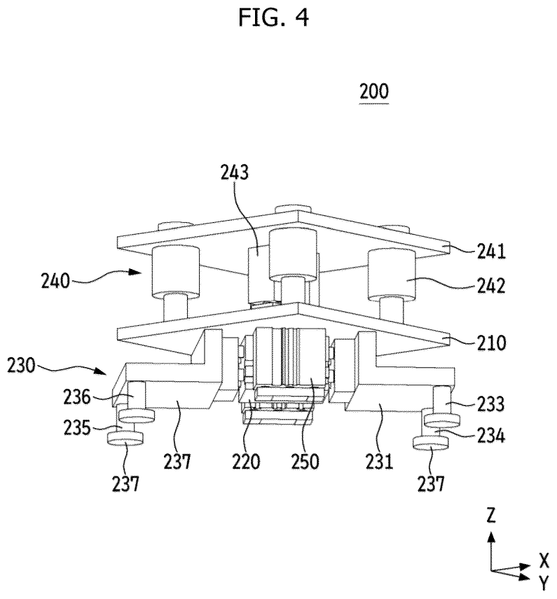

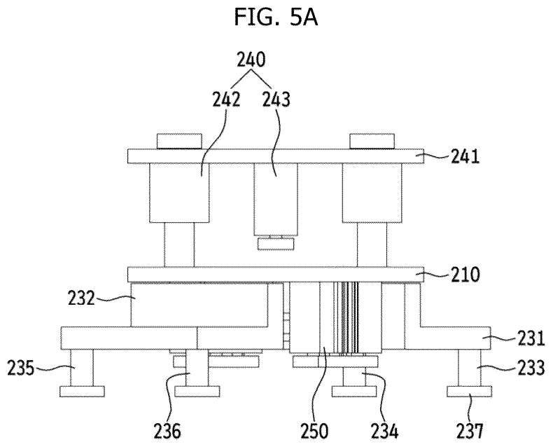

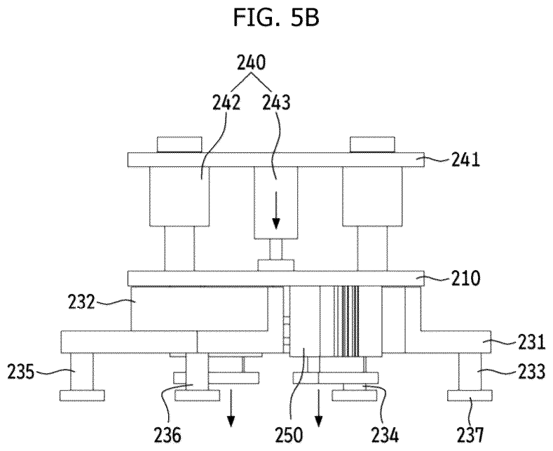

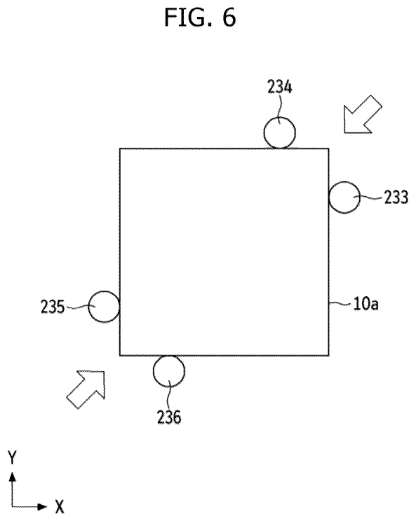

FIG. 3 is a perspective view illustrating the first transport module of the continuous cassette supply apparatus illustrated in FIG. 2, FIG. 4 is a perspective view illustrating the first cassette gripping apparatus of the first transport module illustrated in FIG. 3, FIGS. 5A and 5B are front views illustrating the first cassette gripping apparatus illustrated in FIG. 4, and FIG. 6 is a reference view illustrating the first cassette gripping apparatus illustrated in FIGS. 5A and 5B from above.

Referring to FIGS. 3 to 6, the first cassette gripping apparatus 200 of the first transport module 110 may include a first plate 210, a first cylinder 220, a gripper 230, and an impact absorption part 240.

In the first cassette gripping apparatus 200, the first cylinder 220 and the gripper 230 may be disposed on one side with respect to the first plate 210, and the impact absorption part 240 may be disposed on the other side thereof.

The first cylinder 220 may operate so that members of the gripper 230 move away from or toward each other on the one side of the first plate 210. The first cylinder 220 may be configured as one cylinder or may be configured so that a pair of cylinders operate in different directions.

Further, the gripper 230 may include a first connection member 231, a second connection member 232, and first to fourth guide members 233 to 236.

One side of the first connection member 231 may be coupled to the first cylinder 220, and the other side of the first connection member 231 may have the first guide member 233 and the second guide member 234 spaced apart from each other so that the first guide member 233 and the second guide member 234 can reciprocate together with the first connection member 231. In this case, a direction in which the first cylinder 220 reciprocates and a direction in which the first guide member 233 and the second guide member 234 are disposed on the first connection member 231 may be perpendicular to each other.

Further, one side of the second connection member 232 may be coupled to the first cylinder 220, and the other side of the second connection member 232 has a third guide member 235 and a fourth guide member 236 spaced apart from each other so that the third guide member 235 and the fourth guide member 236 can reciprocate together with the second connection member 232. In this case, the direction in which the first cylinder 220 reciprocates and a direction in which the third guide member 235 and the fourth guide member 236 are disposed on the second connection member 232 may be perpendicular to each other.

Further, the first guide member 233 and the second guide member 234 may be disposed to face each other in the same direction as the third guide member 235 and the fourth guide member 236.

The first guide member 233 to the fourth guide member 236 may have a flange member 237 that protrudes in a circumferential direction at each tip thereof.

In this case, the quadrilateral cassette may be gripped as the first connection member 231 and the second connection member 232 move toward each other, toward two vertices disposed in the diagonal direction. That is, each of the first guide member 233 to the fourth guide member 236 comes into contact with a corresponding one of four sides of the cassette to grip the cassette at a certain location. That is, the first connection member 231 and the second connection member 232 may move in a direction in which the first connection member 231 and the second connection member 232 move toward each other on the same line to grip the cassette. Specifically, the first guide member 233 and the fourth guide member 236 may move in a direction in which the first guide member 233 and the fourth guide member 236 move toward each other on a virtual line defined as a first line, and the second guide member 234 and the third guide member 235 may move in a direction in which the second guide member 234 and the third guide member 235 move toward each other on a virtual line defined as a second line. Here, the first line and the second line may be parallel to each other.

Further, a second cylinder 250 may be provided adjacent to the first cylinder 220 on the one side of the first plate 210.

The second cylinder 250 selectively protrudes toward an area of an upper surface of the cassette from the first plate 210 to press the area so that the other area of the upper surface of the cassette can be supported by the flange member 237 and the cassette can be fixed in a z-axis direction.

For example, FIG. 5A shows a state prior to the second cylinder 250 protruding toward the upper surface of the cassette in a state in which an edge area of a lower surface of the cassette is supported by the flange member 237, and FIG. 5B shows a state in which the second cylinder 250 protrudes toward the upper surface of the cassette.

Therefore, as illustrated in FIG. 6, when the first cylinder 220 operates and the first connection member 231 and the second connection member 232 move toward each other, an upper surface 10a of the cassette coming into contact with the first guide member 233 to the fourth guide member 236 may be automatically aligned in the x-axis and y-axis directions, and when the second cylinder 250 operates to press the upper surface of the cassette, the cassette may be fixed in the z-axis direction.

Further, the impact absorption part 240 may be provided on the other side of the first plate 210.

The impact absorption part 240 can include a second plate 241, dampers 242, and a spacing maintenance part 243.

The second plate 241 may be spaced apart from the first plate 210 on the other side of the first plate 210.

Further, the dampers 242 may connect the first plate 210 and the second plate 241 to elastically support the first plate 210 and the second plate 241. In FIG. 4, an example in which four dampers 242 are provided to correspond to respective vertex areas of the second plate 241 is illustrated, and the number of dampers is not limited thereto.

Further, the spacing maintenance part 243 may be disposed in a central area between the first plate 210 and the second plate 241 to selectively extend from one of the plates to the other plate. For example, FIG. 4 illustrates an example in which the spacing maintenance part 243 is installed on the second plate 241 and extends toward the first plate 210.

When the spacing maintenance part 243 extends and a spacing between the first plate 210 and the second plate 241 is fixed, there is an advantage in that a location of the first plate 210 from the second plate 241 is prevented from being changed for precise locational movement, for example, in a situation such as a case in which the first transport module 110 moves down in units of pitch and a case in which the first transport module 110 moves to grip a new cassette.

On the other hand, the spacing between the first plate 210 and the second plate 241 can be flexibly changed through compression of the spacing maintenance part 243, and an effect of preventing impact from being transmitted to the first cassette gripping apparatus 200 can be expected when the cassette is transferred from the first cassette gripping apparatus 200 to the second cassette gripping apparatus 300.

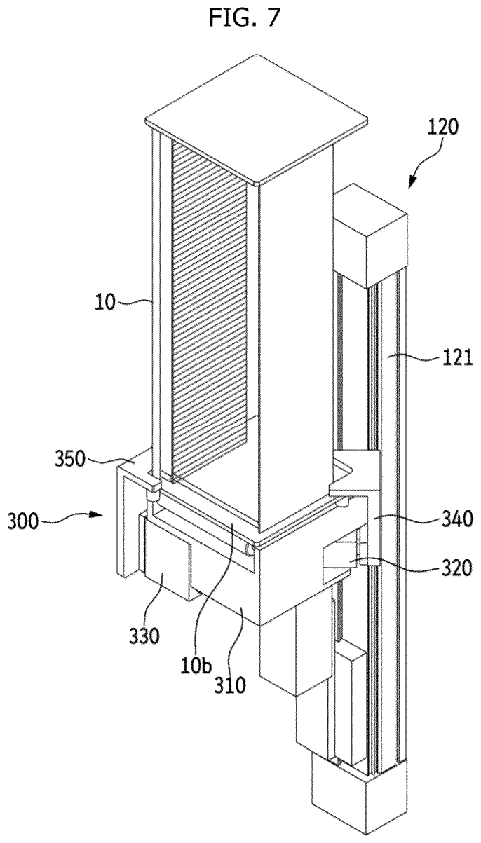

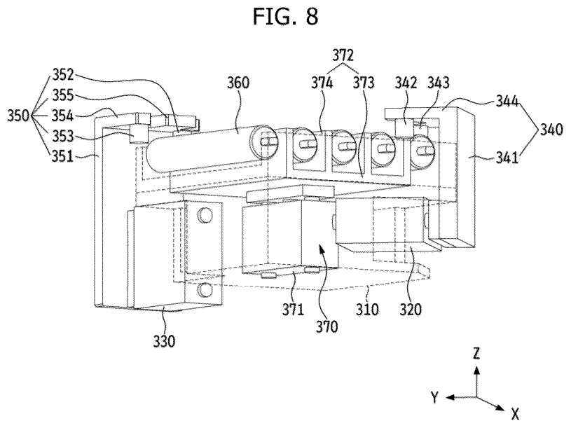

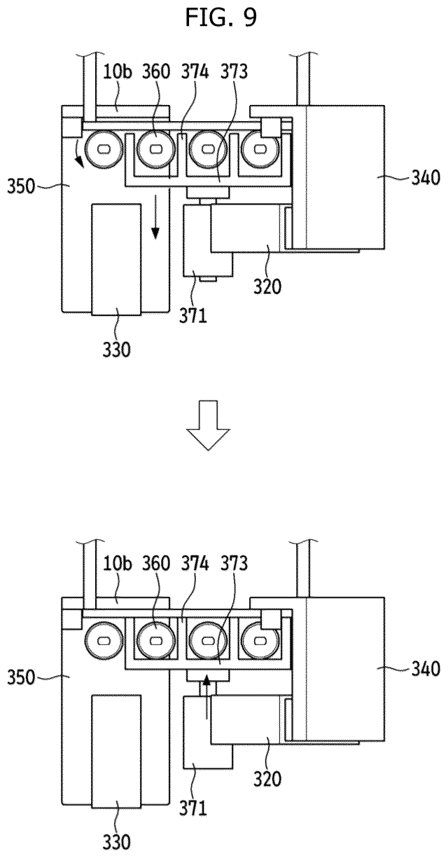

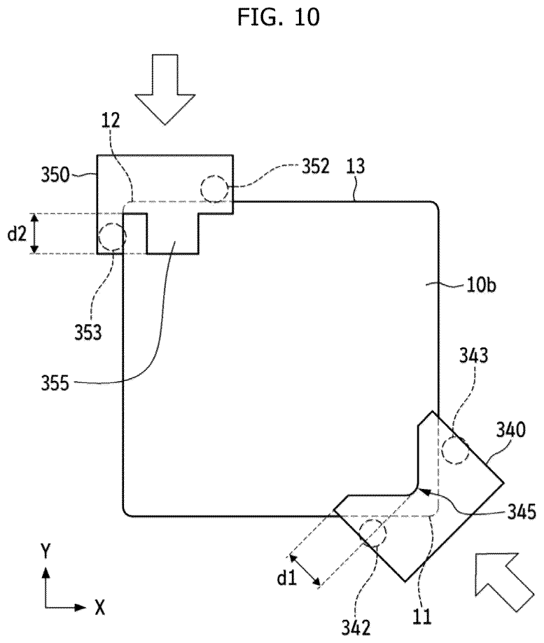

FIG. 7 is a perspective view illustrating the second transport module of the continuous cassette supply apparatus illustrated in FIG. 2, FIG. 8 is a reference view illustrating the second cassette gripping apparatus of the first transport module illustrated in FIG. 7, FIG. 9 is a reference diagram illustrating an operating state of the second cassette gripping apparatus illustrated in FIG. 8, and FIG. 10 is a reference diagram illustrating the second cassette gripping apparatus illustrated in FIG. 9 from above.

Referring to FIGS. 7 to 10, the second cassette gripping apparatus 300 of the second transport module 120 may grip the cassette transferred from the first cassette gripping apparatus 200 from below.

The second cassette gripping apparatus 300 may include a housing 310, a third cylinder 320, a fourth cylinder 330, a first gripper 340, a second gripper 350, roller parts 360, and a pressing module 370.

First, the housing 310 may be made in an approximately rectangular parallelepiped shape, the third cylinder 320 may be disposed on one side of the housing 310, and the fourth cylinder 330 may be disposed on the other side thereof.

Further, the first gripper 340 may be coupled to the third cylinder 320, and the second gripper 350 may be coupled to the fourth cylinder 330.

Therefore, the first gripper 340 and the second gripper 350 may operate to move away from each other when the third cylinder 320 and the fourth cylinder 330 each extend outward, and to move toward each other when the third cylinder 320 and the fourth cylinder 330 are each compressed inward.

The first gripper 340 and the second gripper 350 may operate to move away from or toward each other with respect to the two vertices in a diagonal direction of the quadrilateral cassette.

The first gripper 340 can include a first connection member 341, a first guide member 342, and a second guide member 343.

The first connection member 341 may be provided with a first bent member 344 having one side connected to the third cylinder 320 and extending upward and the other side bent at a right angle.

The first guide member 342 and the second guide member 343 may be disposed apart from each other below the first bent member 344.

In this case, the first bent member 344 may have an avoidance structure 345 so that the first bent member 344 is prevented from coming into contact with a structure installed in an upper portion of the cassette. For example, in the first bent member 344, the avoidance structure 345 may be formed to be concave toward one vertex in an area other than both areas in which the first guide member 342 and the second guide member 343 are disposed.

Further, the second gripper 350 may have a different shape from the first gripper 340. The second gripper 350 may include a second connection member 351, a third guide member 352, and a fourth guide member 353.

The second connection member 351 may be provided with a second bent member 354 having one side connected to the fourth cylinder 330 and extending upward and the other side thereof bent at a right angle.

The third guide member 352 and the fourth guide member 353 may be disposed apart from each other below the second bent member 354.

In this case, the second connection member 351 may include a protrusion member 355 that extends to further protrude from the second bent member 354. The protrusion member 355 may be disposed to overlap the upper surface of the cassette when the second gripper 350 moves toward and becomes adjacent to the cassette. It is apparent that when the second gripper 350 moves toward the cassette and the protrusion member 355 overlaps the upper surface of the cassette, the third guide member 352 and the fourth guide member 353 may be disposed to come into contact with both sides of the cassette adjacent to each other at the other vertex thereof.

Referring to FIG. 10, the first gripper 340 and the second gripper 350 may move in different directions. The first gripper 340 may be disposed to reciprocate in a diagonal direction from one vertex 11 to another vertex 12 in the diagonal direction of the cassette 10, and the second gripper 350 may be disposed to reciprocate in a direction perpendicular to one side 13 of the cassette adjacent to the other vertex 12. That is, the first gripper 340 may move in the diagonal direction of the cassette, and the second gripper 350 may move in a direction perpendicular to the one side 13 of the cassette.

Specifically, the first gripper 340 may reciprocate on a third line defined as a virtual straight line connecting the two vertices 11 and 12 of the cassette 10. The second gripper 350 may reciprocate on a fourth line, which is different from the third line. Here, the fourth line may be a virtual straight line extending in a direction perpendicular to a direction in which the one side 13 of the cassette 10 extends. In this case, the third line and the fourth line may not be parallel to each other. The third line and the fourth line may intersect with each other. An intersection angle formed when the third line and the fourth line intersect with each other may not be a right angle. For example, the intersection angle may be an obtuse angle or an acute angle depending on a measurement criterion or location thereof.

Therefore, a diagonal distance d1 that the first gripper 340 moves toward the one vertex 11 of the cassette 10 to grip the cassette 10 may be relatively greater than a distance d2 that the second gripper 350 moves toward the one side 13 of the cassette 10. It is apparent that when the first gripper 340 and the second gripper 350 move toward each other, the cassette may be automatically aligned in the x-axis and y-axis directions.

Further, a plurality of the roller parts 360 may be installed so that cylindrical roller structures are exposed at an upper portion of the housing 310 and may be disposed to selectively come into contact with a lower surface 10b of the cassette 10. When the lower surface 10b of the cassette comes into contact with the roller parts 360, the cassette may be discharged to the outside in rolling contact with the roller parts 360. Although not shown in the drawings, the plurality of roller parts 360 may be installed so that their heights gradually decrease in a direction in which the cassette is discharged to the outside.

Further, the pressing module 370 may be disposed to move up or down with respect to the lower surface 10b of the cassette inside the housing 310 and function to selectively fix the cassette with respect to the z-axis direction.

The pressing module 370 may include a fifth cylinder 371 provided between the third cylinder 320 and the fourth cylinder 330 on the housing 310, and a pressing plate 372 that is connected to the fifth cylinder 371 and linearly reciprocates from the housing 310 toward the lower surface 10b of the cassette.

The fifth cylinder 371 may operate in a direction orthogonal to a direction in which the third cylinder 320 or the fourth cylinder 330 operates.

Further, the pressing plate 372 can include a horizontal plate 373 and a plurality of vertical plates 374.

The horizontal plate 373 may have a lower portion connected to the fifth cylinder 371 on the housing 310 and may be disposed to move up or down according to an operation of the fifth cylinder 371.

The vertical plate 374 may protrude toward the lower surface 10b of the cassette on the horizontal plate 373, may be disposed between the plurality of roller parts 360, and may be disposed apart from the respective roller parts.

In this case, the vertical plate 374 may be formed to be at least larger than a diameter of the roller part 360 (or with a higher height).

Accordingly, when the pressing plate 372 moves up, the pressing plate 372 may come into contact with the lower surface 10b of the cassette, and when the pressing plate 372 moves down, the cassette 10 may come into contact with the roller parts 360.

For example, when the fifth cylinder 371 extends and moves up, the pressing plate 372 moves up to press the lower surface 10b of the cassette 10, and in this case, the first gripper 340 and the second gripper 350 are disposed to come into contact with the respective sides of the cassette 10 and overlap respective parts of the upper surface so that the cassette 10 can be pressed and fixed in the z-axis direction between the pressing plate 372 and the first and second grippers 340 and 350. On the other hand, when the fifth cylinder 371 is compressed and moved down, the pressing plate 372 moves down and the lower surface 10b of the cassette 10 is placed on the roller parts 360. In this case, the first gripper 340 and the second gripper 350 are pulled away from the two vertices of the cassette 10, so that the cassette 10 can be discharged to the outside (or the collection part 132 (see FIG. 1)) through a rolling motion on the roller parts 360.

Therefore, with the cassette gripping apparatus according to the embodiment of the present invention, it is possible to minimize impact transmitted to the substrates when the gripping apparatus grips the cassette, to grip the cassette in an automatically aligned state through a single operation, to fix the cassette so that the cassette does not shake when the cassette is transferred from the first cassette gripping apparatus to the second cassette gripping apparatus, and to automatically discharge the cassette whose substrates have been separated from the second cassette gripping apparatus.

Although not illustrated in the drawing, the substrate according to the present embodiment may be a substrate for manufacture of solar cells. For example, the substrate according to the present embodiment may be a substrate for manufacture of tandem solar cells, and the continuous cassette supply apparatus according to the present embodiment may be an apparatus that can continuously supply the substrates disposed in the cassette by supplying and collecting the cassettes in a timely manner.

In brief, the tandem solar cell (not illustrated) may include a plurality of solar cells. For example, the tandem solar cell may include a first solar cell and a second solar cell disposed on the first solar cell.

The first solar cell may include any one of a variety of solar cells, such as a crystalline silicon (Si) solar cell, a polycrystalline silicon solar cell, a CIGS-based solar cell, a gallium arsenide (GaAs) solar cell, a dye sensitized solar cell, an organic solar cell, and a compound solar cell.

The second solar cell may include a perovskite solar cell. The second solar cell may include a recombination layer, a hole transport layer, a perovskite light absorption layer, a buffer layer, an electron transport layer, and an upper electrode layer.

The recombination layer (not illustrated) may be a layer that induces recombination of electrons and holes generated in at least one of the first solar cell and the perovskite light absorption layer.

The perovskite light absorption layer may be disposed on the recombination layer. The perovskite light absorption layer may be a light absorption layer and may include a perovskite material.

The upper electrode layer may be disposed on the perovskite light absorption layer. The upper electrode layer may be an area on which light is incident and may include a transparent conductive material.

The hole transport layer may be disposed between the recombination layer and the perovskite light absorption layer. The hole transport layer may be a layer that transports holes formed in the perovskite light absorption layer and blocks the movement of electrons.

The electron transport layer may be disposed between the perovskite light absorption layer and the upper electrode layer. The electron transport layer may be a layer that transports electrons formed in the perovskite light absorption layer and blocks holes.

The buffer layer may be disposed on the perovskite light absorption layer. Specifically, the buffer layer may be disposed between the perovskite light absorption layer and the electron transport layer. The buffer layer can protect the perovskite light absorption layer from moisture, heat, or the like. Further, the buffer layer can serve as an electrical buffer between the perovskite light absorption layer and the electron transport layer.

In one embodiment, the continuous cassette supply apparatus 100 may be an apparatus that supplies the substrates 30 to a process for forming at least one layer included in the second solar cell. For example, the continuous cassette supply apparatus 100 may be an apparatus that supplies the substrates to a process area for forming the buffer layer on the substrate 30 on which a predetermined layer has been formed. Specifically, the substrate 30 on which the perovskite light absorption layer is formed may be accommodated in the cassette. Thereafter, the cassette may be provided to the continuous cassette supply apparatus 100, and the substrates 30 may be extracted one by one and transferred to the next process by the separation module 140 of the continuous cassette supply apparatus 100.

The transferred substrates 30 may be moved onto a tray by a separate transport member. The tray may include a plurality of through holes corresponding to the substrates 30. The transport member may place each of the plurality of substrates 30 in the through hole corresponding to the substrate 30. The tray may support the plurality of substrates 30 placed in the through holes.

When the plurality of substrates 30 are placed on the tray, the tray may be moved to a buffer layer formation area. For example, the tray may be transported to a physical vapor deposition (PVD) device for buffer layer formation. For example, a buffer layer formation device may be an evaporator. Afterwards, a buffer layer may be formed on the substrate. For example, a buffer layer including at least one of lithium fluoride (LiF) and a fullerene (C₆₀) may be formed on the substrate.

That is, with the continuous cassette supply apparatus 100 according to the embodiment of the present invention, the cassettes may be continuously supplied and discharged, and in this process, the cassettes may be effectively aligned and gripped. This also allows alignment characteristics of the substrates accommodated in the cassettes to be improved. Accordingly, it is possible to continuously supply the substrates 30 to a subsequent process, such as to the tray having the plurality of through holes formed therein, with an effective cycle time. Further, there is an effect that there is no need to secure additional installation space since the additional installation space is not required due to vertical disposition of the first transport module and the second transport module, and the present invention can be easily applied to other cassette supply apparatuses since installation space is not limited.

With the cassette gripping apparatus according to the embodiment of the present invention, firstly, it is possible to minimize impact transmitted to the substrates when the gripping apparatus grips the cassette, secondly, it is possible to grip the cassette in an automatically aligned state through a single operation, thirdly, it is possible to fix the cassette so that the cassette does not shake when the cassette is transferred from the first cassette gripping apparatus to the second cassette gripping apparatus, and fourthly, it is possible to automatically discharge the cassette whose substrates have been separated from the second cassette gripping apparatus.

The effects of the present invention are not limited to the effects mentioned above, and other effects that are not mentioned will be clearly understood by those skilled in the art from the description of the claims.

Although specific embodiments have been illustrated and described to exemplify the technical spirit of the present invention, the present invention is not limited to the same configuration and operation as those of the specific embodiments described above, and various modifications can be implemented without departing from the scope of the present invention. Therefore, such modifications should also be considered to fall within the scope of the present invention, and the scope of the present invention should be determined by the claims below.

What is claimed is:

1. A cassette gripping apparatus comprising:
a first plate;
a first cylinder provided on one side of the first plate; and
grippers coupled to the first cylinder to grip both sides of a cassette, wherein
the grippers operate to move away from or toward each other with respect to opposite vertices in a diagonal direction of the cassette.

2. The cassette gripping apparatus as claimed in claim 1, wherein the grippers include:
a first guide member and a second guide member disposed on two sides adjacent to each other at one of the vertices of the quadrilateral cassette;
a first connection member configured to connect the first guide member and the second guide member to one side of the first cylinder;
a third guide member and a fourth guide member disposed on two sides adjacent to each other at the other vertex of the cassette; and
a second connection member configured to connect the third guide member and the fourth guide member to the other side of the first cylinder.

3. The cassette gripping apparatus as claimed in claim 2, wherein, when the first and second guide members and the third and fourth guide members move toward each other, the cassette is automatically aligned in x-axis and y-axis directions.

4. The cassette gripping apparatus as claimed in claim 2, wherein each of the first to fourth guide members includes a flange member that protrudes in a circumferential direction at a tip thereof and supports the other side of the cassette.

5. The cassette gripping apparatus as claimed in claim 4, further comprising:
a second cylinder that is adjacent to the first cylinder and is configured to press and fix one side of the cassette,
wherein, when the second cylinder presses the one side of the cassette, the other side of the cassette is supported by and fixed to the flange member.

6. The cassette gripping apparatus as claimed in claim 2, further comprising:
an impact absorption part provided on the other side of the first plate,
wherein the impact absorption part includes
a second plate spaced apart from the other side of the first plate;
a plurality of dampers elastically connecting the first plate and the second plate; and
a spacing maintenance part configured to selectively maintain a set spacing between the first plate and the second plate.

7. A cassette gripping apparatus comprising:
a housing;
a third cylinder provided on one side of the housing;
a fourth cylinder provided on the opposite side of the third cylinder on the housing;
a first gripper coupled to the third cylinder to grip one side of a cassette; and
a second gripper coupled to the fourth cylinder to grip the other side of the cassette,
wherein the first gripper and the second gripper operate to move away from or toward each other with respect to opposite vertices in a diagonal direction of the cassette.

8. The cassette gripping apparatus as claimed in claim 7,
wherein the first gripper is disposed to reciprocate in a diagonal direction from one of the vertices to the other vertex in the diagonal direction of the quadrilateral cassette, and
the second gripper is disposed to reciprocate in a direction perpendicular to one side adjacent to the other vertex.

9. The cassette gripping apparatus as claimed in claim 8, wherein the second gripper is formed to have a relatively shorter movement distance than the first gripper.

10. The cassette gripping apparatus as claimed in claim 7,
wherein the first gripper includes a first guide member and a second guide member disposed on respective adjacent sides at one vertex of the cassette, and a first connection member connected to the third cylinder to move the first guide member and the second guide member away from or toward the one vertex, and
the second gripper includes a third guide member and a fourth guide member disposed on respective adjacent sides at the other vertex of the cassette, and a second connection member connected to the fourth cylinder to move the third guide member and the fourth guide member away from or toward a side adjacent to the other vertex.

11. The cassette gripping apparatus as claimed in claim 10, wherein, when the first gripper and the second gripper move toward each other, the cassette is automatically aligned in x-axis and y-axis directions.

12. The cassette gripping apparatus as claimed in claim 10, further comprising a pressing module that includes a fifth cylinder disposed between the third cylinder and the fourth cylinder on the housing, and a pressing plate connected to the fifth cylinder and disposed to linearly reciprocate toward the cassette from the housing.

13. The cassette gripping apparatus as claimed in claim 12, further comprising a plurality of roller parts disposed between the pressing module and the cassette on the housing and configured to move the cassette in a rolling manner when the roller parts are positioned higher than the pressing module.

14. The cassette gripping apparatus as claimed in claim 13, wherein the pressing plate includes
a horizonal plate connected to the fifth cylinder on the housing and provided to move up and down; and
a plurality of vertical plates protruding toward the cassette on the horizontal plate and disposed between one roller part and the other adjacent roller part to be apart from the respective roller parts.

15. A cassette gripping apparatus comprising:
a first transport module configured to grip one end of a cassette and move the cassette in a first direction defined as a direction from a first location to a second location; and
a second transport module configured to grip the other end of the cassette and move the cassette in the first direction,
wherein the first transport module includes a first cassette gripping apparatus configured to grip an upper end of the cassette,
the second transport module includes a second cassette gripping apparatus configured to grip a lower end of the cassette, and
the second transport module includes a first gripper and a second gripper reciprocating in different directions on the second cassette gripping apparatus.
